(19) United States
(12) Patent Application Publication
(10) Pub. No.: US 2015/0108622 A1
(43) Pub. Date: Apr. 23, 2015

(54) INTERCONNECT BOARD AND SEMICONDUCTOR DEVICE

(71) Applicant: SONY CORPORATION, Tokyo (JP)

(72) Inventors: Mitsuhiro Hanabe, Kanagawa (JP); Hideyuki Shikichi, Tokyo (JP)

(73) Assignee: SONY CORPORATION, Tokyo (JP)

(21) Appl. No.: 14/498,017

(22) Filed: Sep. 26, 2014

(30) Foreign Application Priority Data
Oct. 21, 2013 (JP) 2013-218239

(51) Int. Cl. H03H 7/38; H01L 23/66

(52) U.S. Cl. CPC H03H 7/38; H01L 23/66; H01L 2223/6611
USPC 257/664; 333/32

(57) ABSTRACT

Impedance mismatching to be caused in signal transmission paths is reduced, without any restriction being put on the number of layers.

An interconnect board according to an embodiment of the present technique includes: interconnect layers and insulating layers that are alternately stacked; vias that electrically connect the interconnect layers; front-surface-side electrode pads formed on the front-surface side; back-surface-side electrode pads that are formed on the back-surface side and are arranged in an array; and a conductor loop that is formed in a conductor path connecting one of the front-surface-side electrode pads and one of the back-surface-side electrode pads, the conductor loop being formed with interconnects in the interconnect layers and the vias, the conductor loop extending in a direction perpendicular to the thickness direction of the interconnect board.

### CROSS REFERENCE TO RELATED APPLICATIONS

This application claims the benefit of Japanese Priority Patent Application JP 2013-218239 filed on Oct. 21, 2013, the entire contents of which are incorporated herein by reference.

### TECHNICAL FIELD

The present technique relates to an interconnect board having interconnect layers and insulating layers alternately stacked, and a semiconductor device having a semiconductor electronic component mounted on the interconnect board. More particularly, the present technique relates to a technical field for reducing impedance mismatching in signal transmission paths.

### CITATION LIST

### Patent Literature

[PTL 1]
JP 2010-219463 A

### BACKGROUND ART

In recent years, semiconductor electronic components used as microprocessors in computers and portable telephone devices have been made to operate at higher speeds and have more sophisticated functions. In this trend, the number of terminals accompanying each semiconductor electronic component has increased, resulting in narrower terminal spacing.

The terminal spacing in such a semiconductor electronic component greatly differs from the terminal spacing in a circuit board called a motherboard, and therefore, it is difficult to mount a semiconductor electronic component directly on a motherboard.

In view of this, a semiconductor electronic component is connected to a motherboard via an interconnect board.

An interconnect board is formed as a stack structure in which interconnect layers and insulating layers are alternately stacked by a buildup method, for example. The interconnect layers are connected to one another by vias.

Normally, the terminal portion on the surface (back-surface) side of the interconnect board to be connected to a motherboard is formed as a BGA (Ball Grid Array) portion that includes terminals (electrode pads and solder balls) arranged in an array.

Where an interconnect board having a semiconductor electronic component mounted thereon is mounted on a motherboard, impedance mismatching is caused between the signal lines in the interconnect board and the BGA portion, and between the BGA portion and the signal lines in the motherboard. Particularly, in a case where the frequency of transmission signals is relatively high, signal deterioration due to impedance mismatching often occurs and causes a problem. Normally, constant impedance is maintained between the signal lines in an interconnect board and the signal lines in a motherboard by forming microstrip lines or strip lines. In the BGA portion, on the other hand, the parasitic capacitance between the electrode pads and the conductors existing in the vicinity is relatively high, and a local impedance decrease occurs. Due to such a local impedance decrease at the BGA portion, impedance mismatching is caused in the signal transmission paths.

As a technique for reducing impedance mismatching due to such an impedance decrease at the BGA portion of an interconnect board, JP 2010-219463 A discloses a technique for forming a winding conductor pattern (a conductor loop) in a conductor path between the layer having electrode pads formed thereon and the layer having a transmission path formed therein in an interconnect board.

Such a conductor loop functions as a winding wire (an inductor), and accordingly, self-inductance of the conductor loop can be balanced with parasitic capacitance of the electrode pads. That is, the impedance decrease at the BGA portion is suppressed, to reduce impedance mismatching.

### SUMMARY

### Technical Problem

So as to achieve sufficient inductance for the parasitic capacitance generated at the electrode pads of the BGA portion, the number of loops in the conductor loop (the number of coils in a winding wire) is preferably increased.

By the technique disclosed in JP 2010-219463 A, however, the loop extending direction of the conductor loop is the same as the thickness direction of the interconnect board, and therefore, the number of layers in the interconnect board also needs to be increased so as to increase the number of loops. That is, by the technique disclosed in JP 2010-219463 A, there is a possibility that, when the number of layers in the interconnect board is small, the number of loops in the conductor loop cannot be increased to achieve sufficient inductance, and impedance mismatching cannot be sufficiently reduced.

Therefore, the present technique aims to overcome the above problems, and reduce impedance mismatching in signal transmission paths, without any restriction being put on the number of layers.

### Solution to Problem

An interconnect board according to an embodiment of the present technique includes: interconnect layers and insulating layers that are alternately stacked; vias that electrically connect the interconnect layers; front-surface-side electrode pads formed on the front-surface side; back-surface-side electrode pads that are formed on the back-surface side and are arranged in an array; and a conductor loop that is formed in a conductor path connecting one of the front-surface-side electrode pads and one of the back-surface-side electrode pads, the conductor loop being formed with interconnects in the interconnect layers and the vias, the conductor loop extending in a direction perpendicular to the thickness direction of the interconnect board.

Since the loop extending direction of the conductor loop is perpendicular to the board thickness direction as described above, the number of layers in the interconnect board does not need to be increased so as to increase the number of loops in the conductor loop.

In the interconnect board according to an embodiment of the present technique, one end of the conductor loop is preferably located on the one of the back-surface-side electrode pads. With this arrangement, the conductor loop is located near the back-surface-side electrode pad.

In the interconnect board according to an embodiment of the present technique, an insertion member made of a different material from the material of the insulating layers is preferably placed inside the conductor loop.

Accordingly, a higher degree of freedom is allowed in designing the interconnect board.

In the interconnect board according to an embodiment of the present technique, a magnetic material is preferably placed inside the conductor loop.

With this arrangement, the amount of self-inductance per unit loop number in the conductor loop increases further.

The interconnect board according to an embodiment of the present technique is preferably a coreless board.

Since a coreless board does not include any core layer, it is difficult to maintain a distance between the back-surface-side electrode pads and the conductors in the surrounding area in many cases. In such cases, impedance mismatching becomes relatively large.

In the interconnect board according to an embodiment of the present technique, the conductor loop is preferably formed for each conductor path in a pair of conductor paths for transmitting signals by a differential method, and the conductor loops formed in the pair of the conductor paths preferably have the opposite loop directions from each other between the front-surface-side electrode pads and the back-surface-side electrode pads.

In this structure, the loop directions of the currents flowing in the conductor loops inserted in the pair of conductor paths are the same.

A semiconductor device according to an embodiment of the present technique includes: an interconnect board including: interconnect layers and insulating layers that are alternately stacked; vias that electrically connect the interconnect layers; front-surface-side electrode pads formed on a front-surface side; back-surface-side electrode pads that are formed on a back-surface side and are arranged in an array; and a conductor loop formed in a conductor path connecting one of the front-surface-side electrode pads and one of the back-surface-side electrode pads, the conductor loop being formed with interconnects in the interconnect layers and the vias, the conductor loop extending in a direction perpendicular to the thickness direction of the interconnect board; and a semiconductor electronic component electrically connected to the interconnect board via the front-surface-side electrode pads.

As the semiconductor device according to an embodiment of the present technique includes the above described interconnect board according to an embodiment of the present technique, the number of layers in the interconnect board does not need to be increased so as to increase the number of loops in the conductor loop.

### Advantageous Effects of Invention

According to an embodiment of the present technique, impedance mismatching to be caused in signal transmission paths can be reduced, without any restriction being put on the number of layers.

The effects described above do not limit the present technique, and may be any of the effects disclosed in the present disclosure.

### BRIEF DESCRIPTION OF DRAWINGS

FIG. 1 is a schematic cross-sectional view of the structure of a semiconductor device designed to include an interconnect board as a first embodiment.

FIG. 2 is a perspective view of a conductor loop included in the interconnect board of the first embodiment.

FIG. 3 is a top view of the conductor loop included in the interconnect board of the first embodiment.

FIG. 4 is a perspective view of the structure an interconnect board of a second embodiment has for reducing impedance mismatching.

FIG. 5 is a top view of the structure the interconnect board of the second embodiment has for reducing impedance mismatching.

FIG. 6 is a diagram showing the positional relationship between the stacked vias of a conductor loop and an insertion member.

FIG. 7 is a perspective view of a modification of the structure for reducing impedance mismatching.

FIG. 8 is a top view of the modification of the structure for reducing impedance mismatching.

FIGS. 9A and 9B are diagrams for explaining a modification of the insertion member.

FIG. 10 is a diagram for explaining a modification of an extended interconnect portion.

### DESCRIPTION OF EMBODIMENTS

The following is a description of embodiments according to the present technique.

Explanation will be made in the following order.
<1. First Embodiment>
[1-1. Outline of the structure of a semiconductor device]
[1-2. Structure for reducing impedance mismatching]
[1-3. Summary of the first embodiment]
<2. Second Embodiment>
[2-1. Structures of a semiconductor device and an interconnect board]
[2-2. Summary of the second embodiment]
<3. Modifications>
<4. Present technique>

### 1. First Embodiment

### 1-1. Outline of the Structure of a Semiconductor Device

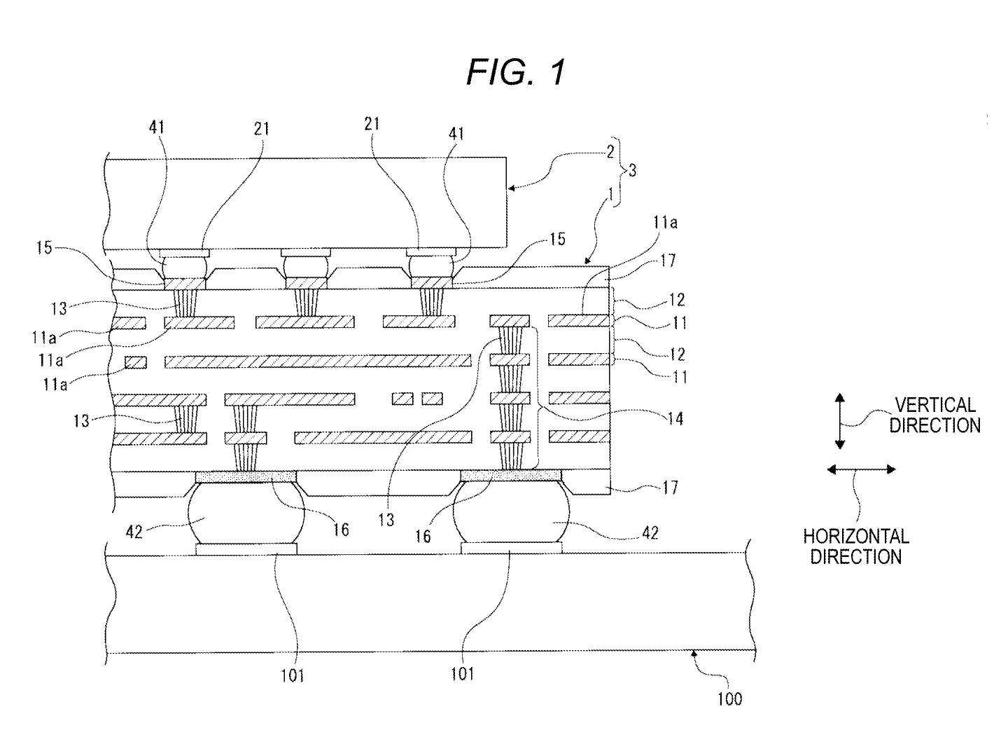

FIG. 1 is a schematic cross-sectional view of the structure of a semiconductor device 3 designed to include an interconnect board 1 as a first embodiment according to the present technique.

In FIG. 1, a motherboard 100 on which the semiconductor device 3 is mounted is also shown. The internal structures of the semiconductor electronic component 2 mounted on the motherboard 100 and the interconnect board 1 are not shown in the cross-sectional view.

In the description below, the direction parallel to the thickness direction of the interconnect board 1 will be referred to as the “vertical direction”, and the direction perpendicular to the board thickness direction (the direction perpendicular to the “vertical direction”) will be referred to as the “horizontal direction”.

As for the interconnect board 1, the surface on the side to which the semiconductor electronic component 2 (the upper side in the drawing) are connected will be referred to as the “front surface”, and the surface on the side to which the motherboard 100 (the lower side in the drawing) is connected will be referred to as the “back surface”.

In FIG. 1, the semiconductor device 1 includes the interconnect board 1 and the semiconductor electronic component 2 mounted on the front-surface side of the interconnect board 1.

The semiconductor electronic component 2 is formed as a so-called IC (Integrated Circuit) chip. The semiconductor electronic component 2 maybe a memory device such as an SDRAM (Synchronous Dynamic Random Access Memory).

The interconnect board 1 is a so-called printed circuit board, is formed by alternately stacking interconnect layers 11 and insulating layers 12, and has vias 13 electrically connecting the interconnect layers 11. The interconnect board 1 including the interconnect layers 11, the insulating layers 12, and the vias 13 is formed by a so-called buildup method. In this example, the interconnect board 1 is a so-called coreless board that has no core layers. For details of coreless boards, please see the following literatures.
Reference literature 1: JP 2002-26171 A
Reference literature 2: JP 2010-161419 A

In each interconnect layer 11, conductors as interconnects 11a are formed in a predetermined pattern. The interconnects 11a are made of copper or gold, for example.

The insulating layers 12 are made of a dielectric resin, and insulate the interconnect layers 11 that are adjacent to each other in the vertical direction from each other.

The vias 13 are formed to electrically connect predetermined interconnects 11a formed in predetermined interconnect layers 11 to each other. The vias 13 are formed by forming through holes in the insulating layers 12 and filling the through holes with a conductor such as copper.

Here, the interconnect board 1 has a structural component formed by stacking vias 13 on one another. Specifically, there is a structural component formed by alternately stacking vias 13 and interconnects 11a. Hereinafter, such a structural component will be referred to as “stacked vias 14”.

Front-surface-side electrode pads 15 for electrically connecting to the semiconductor electronic component 2 are formed on the surface of the insulating layer 12 located on the uppermost position among the insulating layers 12 (hereinafter referred to as the “uppermost insulating layer 12”). A solder resist layer 17 is formed on the surface of the outermost insulating layer 12. Openings are formed in predetermined positions in the solder resist layer 17, and the front-surface-side electrode pads 15 are formed in the respective openings.

Each of the front-surface-side electrode pads 15 is connected to a predetermined interconnect 11a in a predetermined interconnect layer 11 through a corresponding via 13. Solder balls 41 are formed on the respective front-surface-side electrode pads 15, and these solder balls 41 are connected to corresponding electrode pads 21 among electronic-component-side electrode pads 21 formed on the back-surface side of the semiconductor electronic component 2. With this structure, interconnects such as signal lines for transmitting various signals, a power supply line, and a GND line, which are formed in the semiconductor electronic component 2, are electrically connected to the corresponding interconnects formed in the interconnect board 1.

Back-surface-side electrode pads 16 for electrically connecting to the motherboard 100 are formed on the back surface of the insulating layer 12 located in the lowermost position among the insulating layers 12 (hereinafter referred to as the “lowermost insulating layer 12”). Another solder resist layer 17 is formed on the back surface of the lowermost insulating layer 12, and the back-surface-side electrode pads 16 are formed in respective openings formed in predetermined positions in the solder resist layer 17.

Each of the back-surface-side electrode pads 16 is connected to a predetermined interconnect 11a in a predetermined interconnect layer 11 through a corresponding via 13. Solder balls 42 are formed on the respective back-surface-side electrode pads 16, and these solder balls 42 are connected to corresponding electrode pads 101 among motherboard-side electrode pads 101 formed on the front-surface side of the motherboard 100. With this structure, interconnects such as signal lines for transmitting various signals, a power supply line, and a GND line, which are formed in the semiconductor electronic component 2, are electrically connected to the corresponding interconnects formed in the motherboard 100 through the corresponding interconnects formed in the interconnect board 1.

In the interconnect board 1 of this example, the back-surface-side electrode pads 16 are formed in an array, and these back-surface-side electrode pads 16 and the solder balls 42 connected to the back-surface-side electrode pads 16 form a so-called BGA (Ball Grid Array) portion.

As for the signal transmission paths from the front-surface-side electrode pads 15 to the back-surface-side electrode pads 16 (the BGA portion) in the interconnect board 1, the signal transmission path portion minus the BGA portion will be hereinafter referred to as the “signal line portion”.

Although not shown in the drawings, in the interconnect board 1 of this example, the “signal line portion” is subjected to impedance control by so-called strip lines or microstrip lines.

### 1-2. Structure for Reducing Impedance Mismatching

In the BGA portion of the interconnect board 1 connected to the motherboard 100, a local impedance decrease occurs in the BGA portion due to parasitic capacitance generated between the back-surface-side electrode pads 16 and peripheral conductors. Due to such a local impedance decrease in the BGA portion, impedance mismatching occurs between the “signal line portion” in the interconnect board 1 and the BGA portion, and between the BGA portion and the signal lines in the motherboard 100.

So as to reduce such impedance mismatching to be caused in the BGA portion, a conductor loop 18 using interconnects 11a formed in interconnect layers 11 and vias 13 are formed in the conductor path connecting a front-surface-side electrode pad 15 and a back-surface-side electrode pad 16 in this embodiment.

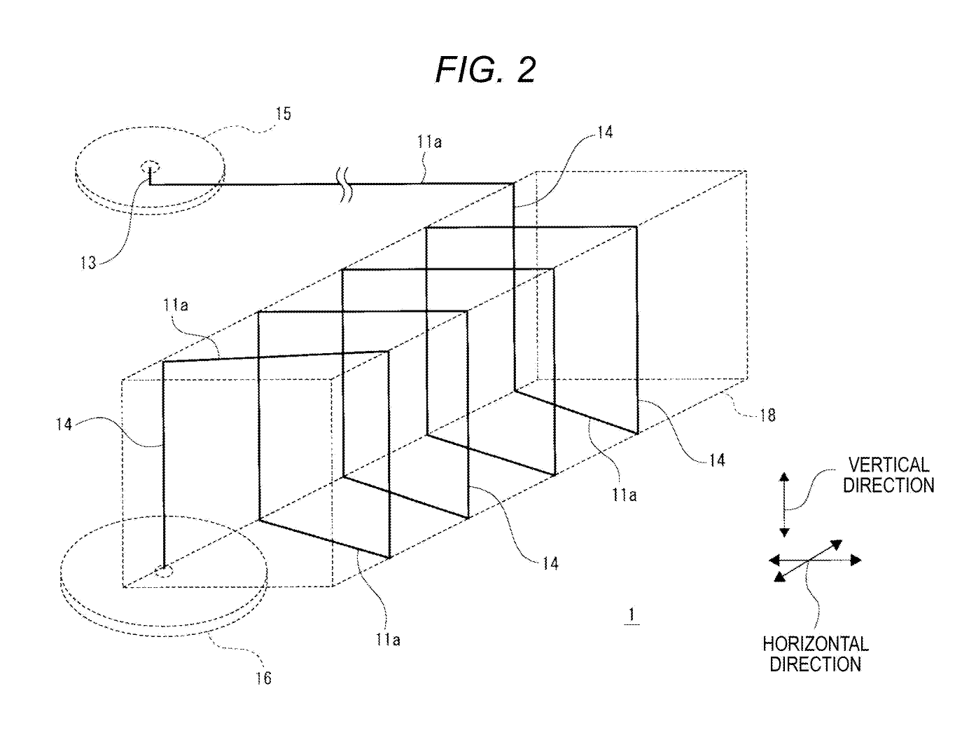

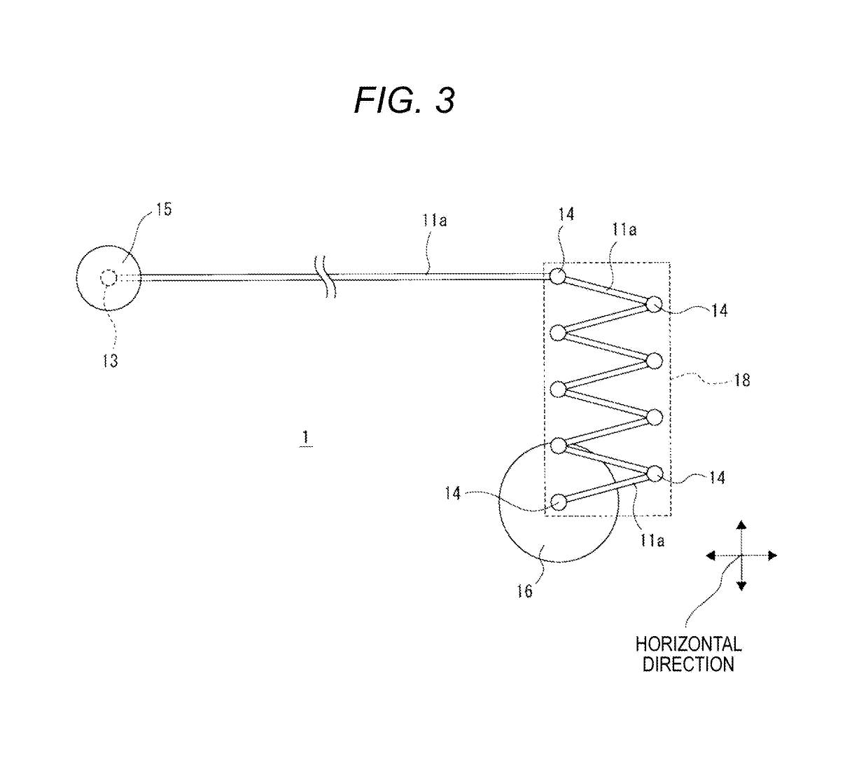

FIGS. 2 and 3 are diagrams for explaining a conductor loop 18. FIG. 2 is a schematic perspective view of a conductor loop 18 formed in the interconnect board 1, a front-surface-side electrode pad 15, an interconnect 11a connecting the front-surface-side electrode pad 15 and the conductor loop 18, and a back-surface-side electrode pad 16. FIG. 3 is a schematic top view of the conductor loop 18, the front-surface-side electrode pad 15, the interconnect 11a, and the back-surface-side electrode pad 16 (seen from the opposite side from the front surface of the interconnect board 1).

Although only one of the signal transmission paths formed in the interconnect board 1 is shown in FIGS. 2 and 3, a conductor loop 18 can be formed for each of the signal transmission paths.

As shown in the drawings, a conductor loop 18 in this embodiment is formed with stacked vias 14 and interconnects 11a, and the direction in which the loops extend (hereinafter referred to as the “loop extending direction”) is the same as the horizontal direction.

Specifically, the conductor loop 18 in this case is formed by forming two rows of stacked vias 14 in the horizontal direction, with the ends of the stacked vias 14 closest to each other between the rows being connected by an interconnect 11a. Here, the ends of the stacked vias 14 are connected by the interconnects 11a alternately on the front-surface side and the back-surface side of the board between the respective sets of the stacked vias 14, so as to form the conductor loop 18 as a loop-like conductor.

The above described conductor loop 18 is equivalent to a winding wire (an inductor) inserted into a conductor path as a signal transmission path, and accordingly, self-inductance of the conductor loop 18 can be balanced with parasitic capacitance of the back-surface-side electrode pads 16. That is, the impedance decrease at the BGA portion is suppressed, to reduce impedance mismatching in the signal transmission paths.

In the conductor loop 18 of this embodiment, the direction in which the loops extend is the direction perpendicular to the board thickness direction. Therefore, in increasing the number of loops (the number of coils in the winding wire) in the conductor loop 18, there is no need to increase the number of layers in the interconnect board 1. Specifically, the smallest number of layers necessary in forming the conductor loop 18 in this embodiment is “3” (two interconnect layers 11 and one insulating layer 12), regardless of the number of loops.

In this manner, according to this embodiment, impedance mismatching to be caused in signal transmission paths can be reduced, without any restriction being put on the number of layers in the interconnect board 1.

Although the number of loops in the conductor loop 18 is “4” in FIGS. 2 and 3, the number of loops in the conductor loop 18 may be set at a number required for reducing impedance mismatching, and is not limited to any particular number. Also, in the above described example, each conductor portion extending in the vertical direction in the conductor loop 18 is formed with stacked vias 14. However, each conductor portion extending in the vertical direction may be formed with at least one via 13.

However, the level of inductance to be generated in the conductor loop 18 depends not only on the number of loops but also on the cross-sectional area of the loops (or the cross-sectional area of the winding wire). Therefore, the use of stacked vias 14 in this embodiment is effective in enlarging the cross-sectional area of the loops and efficiently increasing inductance.

In a case where the conductor loop 18 having the horizontal direction as its loop extending direction is used as in this embodiment, the size in the horizontal direction of the board might become larger as the number of loops is set at the necessary number for impedance matching. In a printed circuit board in the past, however, the size restriction in the horizontal dimension is one or more digits smaller than the size restriction in the vertical dimension. Therefore, a certain increase in size in the horizontal direction is allowed. Accordingly, large self-inductance can be more readily achieved in the conductor loop 18 than in a conductor loop in the past having its loop direction in the vertical direction, and a structure for reducing impedance mismatching can be more easily realized.

As shown in FIGS. 2 and 3, the conductor loop 18 having the above described structure has its one end located on a back-surface-side electrode pad 16 in this embodiment. Specifically, in this embodiment, one end portion of the conductor loop 18 is formed as a stacked via 14, and one end of the stacked via 14 is connected to a back-surface-side electrode pad 16.

With this arrangement, the conductor loop 18 is located near the back-surface-side electrode pad 16.

If a parasitic capacitance portion as the back-surface-side electrode pad 16 and an inductance portion as the conductor loop 18 are spatially/electrically separated from each other, a local impedance decrease portion derived from parasitic capacitance and a local impedance increase portion derived from inductance exist independently of each other, resulting in two impedance mismatching portions. In this case, the parasitic capacitance and the inductance do not cancel each other out, and might even cause independent reflection. In view of this, the conductor loop 18 is located near the back-surface-side electrode pads 16 in this embodiment as described above. Accordingly, the impedance decrease portion and the impedance increase portion are located close to each other, so as to sufficiently offset an impedance decrease due to parasitic capacitance with an impedance increase due to the self-inductance of the conductor loop 18, and increase the effect to reduce impedance mismatching.

### 1-3. Summary of the First Embodiment

As described above, in the interconnect board 1 of this embodiment, the interconnect layers 11 and the insulating layers 12 are alternately stacked, the vias 13 electrically connecting the interconnect layers 11 are formed, the front-surface-side electrode pads 15 are formed on the front-surface side, the back-surface-side electrode pads 16 are formed on the back-surface side, and the back-surface-side electrode pads 16 are arranged in an array. In a conductor path connecting a front-surface-side electrode pad 15 and a back-surface-side electrode pad 16, the conductor loop 18 that extends in the direction perpendicular to the board thickness direction is formed as a conductor loop using the interconnects 11a formed in interconnect layers 11 and vias 13.

Since the loop extending direction of the conductor loop 18 is perpendicular to the board thickness direction as described above, the number of layers in the interconnect board 1 does not need to be increased so as to increase the number of loops in the conductor loop 18.

Accordingly, impedance mismatching to be caused in signal transmission paths can be reduced, without any restriction being put on the number of layers.

As impedance mismatching is reduced, multiple reflection of transmission signals can be reduced, and higher signal quality can be achieved.

Since the interconnect board 1 having the above described conductor loop 18 of this embodiment can be manufactured by a buildup method that is used in the past in manufacturing printed circuit boards, there is no need to use any particular additional structure or process. Accordingly, the interconnect board 1 can be realized at low costs.

Also, in the interconnect board 1 of this embodiment, one end of the conductor loop 18 is located on a back-surface-side electrode pad 16.

With this arrangement, the conductor loop 18 is located near the back-surface-side electrode pad 16.

Accordingly, the parasitic capacitance portion as the back-surface-side electrode pad 16 and the inductance portion as the conductor loop 18 can be prevented from existing as impedance mismatching portions independent of each other, and the impedance decrease in the back-surface-side electrode pad 16 can be thoroughly offset with the impedance increase by virtue of the conductor loop 18, to increase the effect to reduce impedance mismatching.

Further, the interconnect board 1 of this embodiment is a coreless board.

Since a coreless board does not include any core layer, it is difficult to maintain a distance between the back-surface-side electrode pads 16 and the conductors in the surrounding area in many cases. In such cases, impedance mismatching becomes relatively large.

Therefore, it is preferable to perform impedance matching by using the conductor loop 18.

Also, not having a core layer, a coreless board have no through holes. Accordingly, transmission loss of high-frequency signals can be reduced, and the semiconductor electronic component (an IC chip) mounted on the interconnect board 1 can be operated at a high speed.

### 2. Second Embodiment

### 2-1. Structures of a Semiconductor Device and an Interconnect Board

A semiconductor device 3A designed to include an interconnect board 1A as a second embodiment is now described.

The semiconductor device 3A of the second embodiment differs from the semiconductor device 3 of the first embodiment in that the interconnect board 1 is replaced with the interconnect board 1A. A schematic cross-sectional view of the semiconductor device 3A should be the same as the cross-sectional view shown in FIG. 1, and therefore, explanation of the structure in cross-section will not be repeated again with reference to a drawing.

Since the interconnect board 1A of the second embodiment differs from the interconnect board 1 of the first embodiment only in the structure for reducing impedance mismatching, only the structure the interconnect board 1A has for reducing impedance mismatching will be described below.

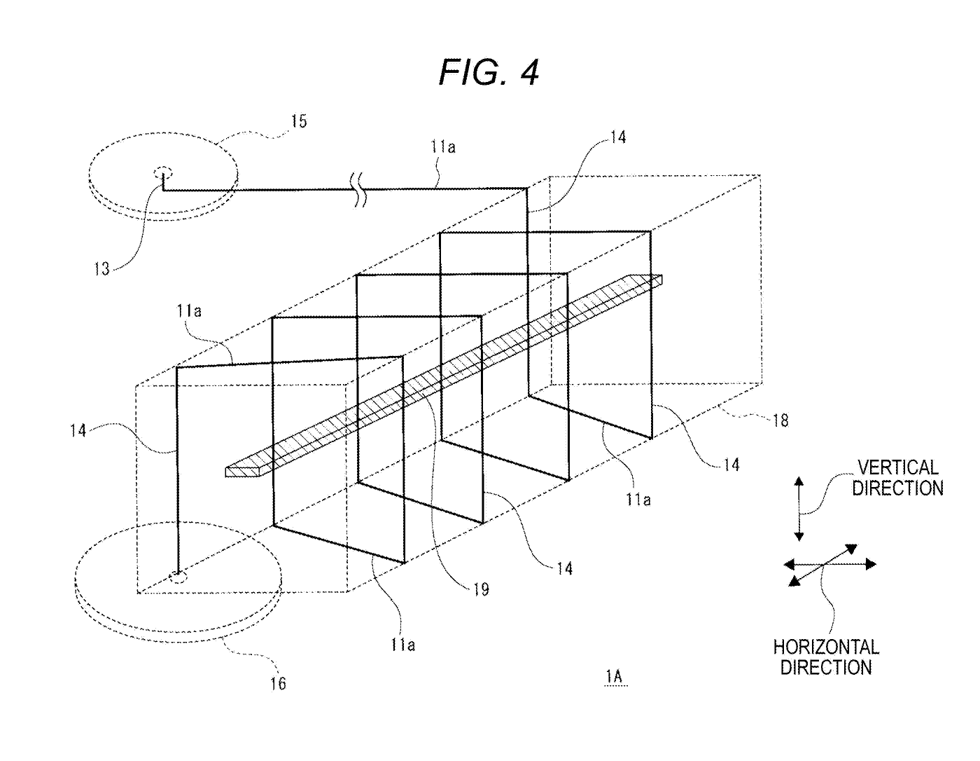

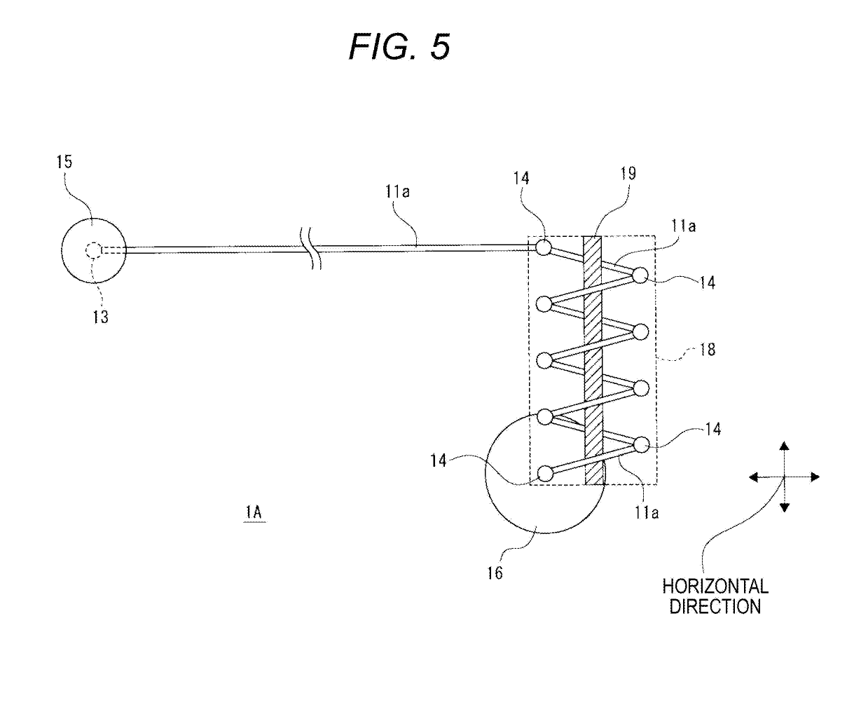

In the description below, the same components as those already described are denoted by the same reference numerals as those used above, and explanation of them will not be repeated. FIGS. 4 and 5 are diagrams for explaining the structure the interconnect board 1A of the second embodiment has for reducing impedance mismatching. Like FIGS. 2 and 3, FIGS. 4 and 5 are a schematic perspective view and a schematic top view, respectively, of the structure for reducing impedance mismatching

Although the structure for reducing impedance mismatching is formed only in one signal transmission path in FIGS. 4 and 5, this structure can also be formed in each of the signal transmission paths in this case.

As shown in FIGS. 4 and 5, an insertion member 19 made of a different material from the material of the insulating layers 12 is placed inside a conductor loop 18 in the second embodiment.

In this example, the insertion member 19 is made of a magnetic material.

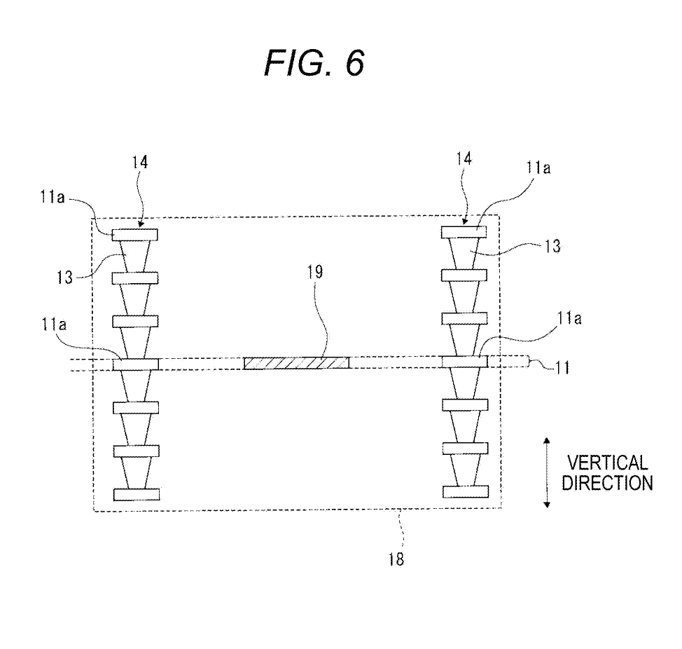

FIG. 6 is a diagram showing the positional relationship between the stacked vias 14 of the conductor loop 18 and the insertion member 19.

As shown in FIG. 6, the insertion member 19 in this example is formed for the interconnect layer 11 located at the center portion in the conductor loop 18 in terms of the vertical direction. Specifically, the insertion member 19 in this example is formed by stacking a magnetic material (such as a ferrite sheet or nickel) on the corresponding insulating layer 12 in the process of stacking the interconnect layers 11 and the insulating layers 12 by a buildup method.

As the insertion member 19 made of a magnetic material is placed inside the conductor loop 18 as described above, the amount of self-inductance per unit loop number in the conductor loop 18 becomes even larger.

Accordingly, the number of loops and the cross-sectional area of each loop required for obtaining the same amount of inductance can be reduced by an amount equivalent to the contribution from the magnetic material, and the conductor loop 18 can be made smaller in size in reducing impedance mismatching.

Here, the amount of self-inductance per unit loop number in the conductor loop 18 increases in proportion to the permeability of the magnetic material inserted into the conductor loop 18. Therefore, the magnetic material to be used as the insertion member 19 is preferably a ferromagnetic material such as a ferrite sheet or nickel as described above. A magnetic material in the form of a sheet can be obtained at a relatively low price, and has high compatibility with the stacking process for printed circuit boards.

Accordingly, the interconnect board 1A having the insertion member 19 made of a magnetic material placed inside the conductor loop 18 as described above can be readily realized by an existing technique.

Although the insertion member 19 is formed in only one interconnect layer 11 in the above described example, the insertion member 19 can be formed for more than one interconnect layer 11. As the number of insertion members 19 made of a magnetic material increases, the total permeability becomes higher. Accordingly, the amount of self-inductance per unit loop number in the conductor loop 18 can be further increased.

### 2-2. Summary of the Second Embodiment

In the interconnect board 1A of the second embodiment, the insertion member 19 made of a different material from the material of the insulating layers 12 is placed inside the conductor loop 18 as described above.

Accordingly, a higher degree of freedom is allowed in designing the interconnect board 1A.

For example, an interconnect may be allowed to extend inside the conductor loop 18, with the insertion member 19 serving as a conductor. With this, the degree of freedom in designing interconnect paths can be increased. Since a magnetic material is placed as the insertion member 19 as described above, the conductor loop 18 can be made smaller in size, and accordingly, a larger space can be secured for the other interconnects. Thus, the degree of freedom in designing the interconnect paths can be increased.

In the second embodiment, the insertion member 19 is made of an insulator, and a magnetic material is contained inside the conductor loop 18.

With this arrangement, the amount of self-inductance per unit loop number in the conductor loop 18 increases further.

Accordingly, the conductor loop 18 can be made even smaller in size in reducing impedance mismatching.

Here, the conductor loop 18 is, so to speak, a detour path, and conductor loss increases in proportion to the number of loops. Therefore, where the insertion member 19 made of a magnetic material is provided to reduce the number of loops as described above, the detour path can be shortened, and conductor loss can be reduced.

### 3. Modifications

Although embodiments according to the present technique have been described so far, the present technique should not be limited to the specific examples described above.

For example, the above description is based on the assumption that the signal transmission paths are compatible with so-called single-ended signaling. However, the present technique can be suitably applied in cases where signal transmission is performed by a so-called differential method (a differential transmission method).

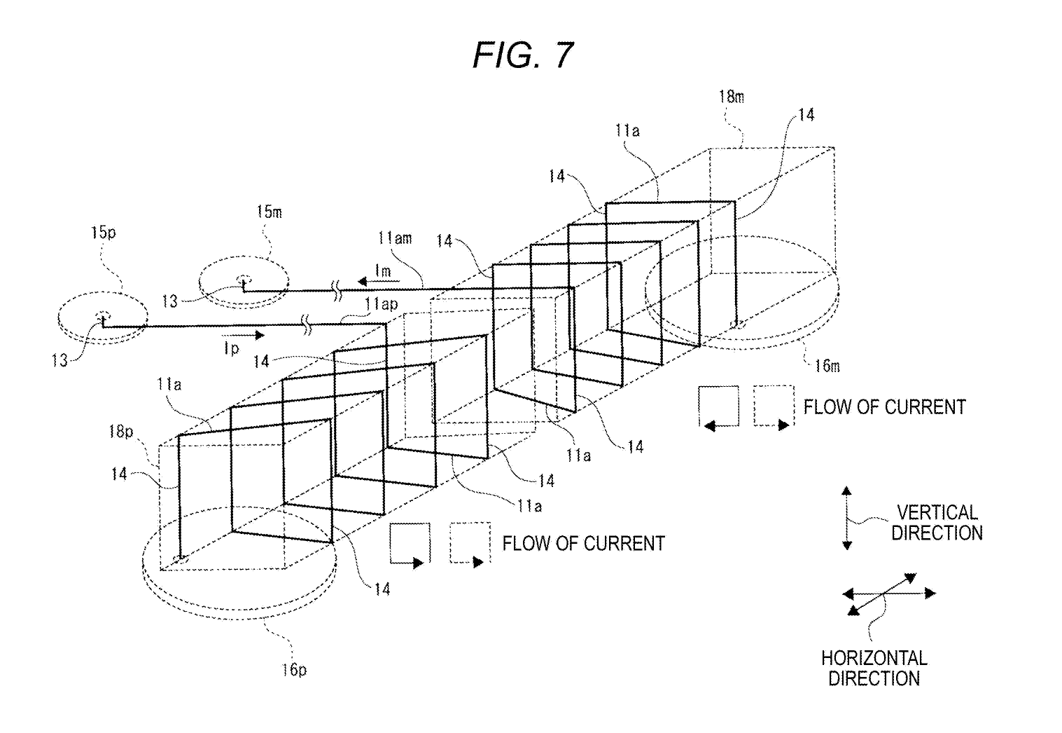

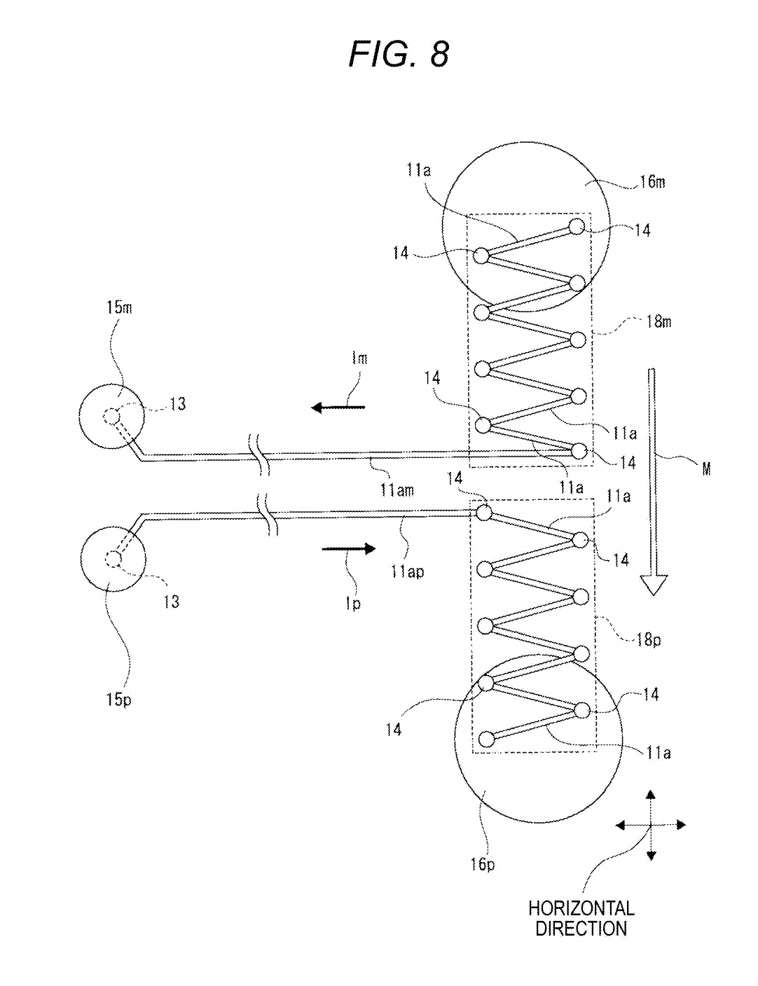

FIGS. 7 and 8 are diagrams for explaining an example structure compatible with signal transmission by a differential method as a modification of the structure for reducing impedance mismatching.

Because of the differential method, there exist a pair of signal transmission paths (conductor paths) that area signal transmission path on the positive polarity side and a signal transmission path on a negative polarity side in this case. For convenience, the front-surface-side electrode pad 15, the back-surface-side electrode pad 16, the conductor loop 18, and the interconnect 11a and the via 13 connecting the conductor loop 18 and the front-surface-side electrode pad 15, which form the signal transmission path on the positive polarity side, are shown as a front-surface-side electrode pad 15p, a back-surface-side electrode pad 16p, a conductor loop 18p, an interconnect 11ap, and a via 13p, respectively. Also, the front-surface-side electrode pad 15, the back-surface-side electrode pad 16, the conductor loop 18, and the interconnect 11a and the via 13 connecting the conductor loop 18 and the front-surface-side electrode pad 15, which form the signal transmission path on the negative polarity side, are shown as a front-surface-side electrode pad 15m, a back-surface-side electrode pad 16m, a conductor loop 18m, an interconnect 11am, and a via 13m, respectively. As shown in FIGS. 7 and 8, in the signal transmission path on the positive polarity side, a current Ip flows from the front-surface-side electrode pad 15 to the back-surface-side electrode pad 16. In the signal transmission path on the negative polarity side, a current Im flows from the back-surface-side electrode pad 16 to the front-surface-side electrode pad 15.

In a case where signal transmission is performed by a differential method, the conductor loop 18p is formed in the signal transmission path on the positive polarity side, and the conductor loop 18m is formed in the signal transmission path on the negative polarity side. Also, the loop directions (the winding directions) of the conductor loop 18p and the conductor loop 18m, or more particularly, the loop directions between the front-surface-side electrode pad 15 and the back-surface-side electrode pad 16, are the opposite from each other (as indicated by solid-line arrows in FIG. 7). In this structure, the loop directions of the currents flowing in the conductor loops 18p and 18m inserted in the pair of conductor paths become the same (as indicated by dashed-line arrows in FIG. 7).

Accordingly, as indicated by a white arrow “M” in FIG. 8, the magnetic field directions of the conductor loop 18p and the conductor loop 18m can be the same. Thus, impedance mismatching can be appropriately reduced in accordance with the differential method, without any magnetic field being canceled out between the conductor loop 18p and the conductor loop 18m.

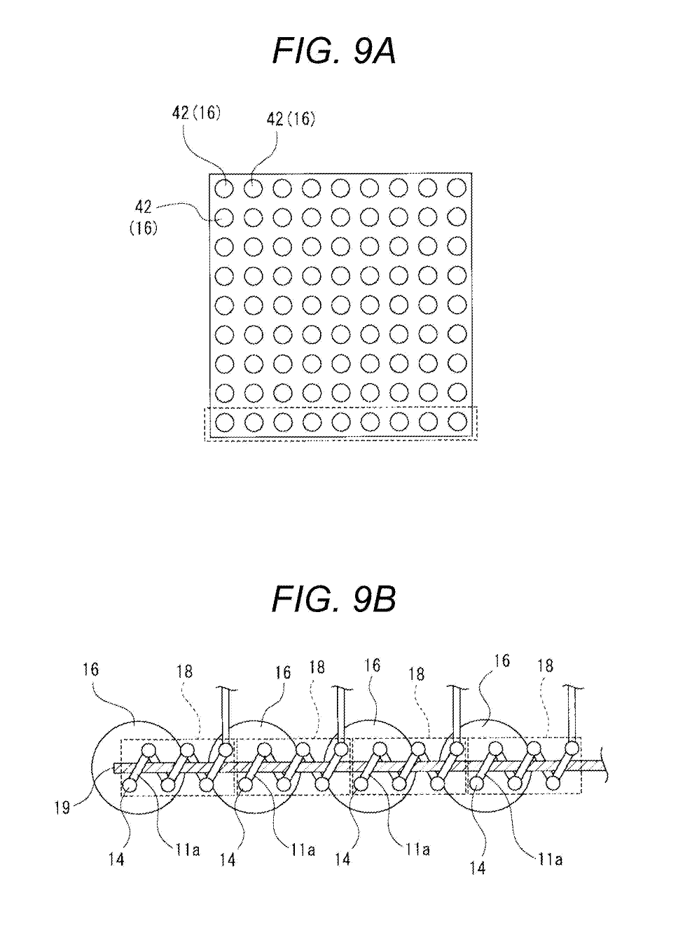

In a case where an insertion member 19 is provided as in the second embodiment, a modification illustrated in FIG. 9 can be formed.

FIG. 9A shows solder balls 42 (back-surface-side electrode pads 16) arranged in the BGA portion formed on the interconnect board 1A, and FIG. 9B schematically shows the conductor loops 18 formed in the one row of solder balls 42 (back-surface-side electrode pads 16) surrounded by a dashed-line in FIG. 9A.

As shown in FIG. 9B, the insertion member 19 can be designed to penetrate through the conductor loops 18.

As the insertion member 19 is designed to penetrate through the conductor loops 18 in this manner, the insertion member 19 can be made to function as the core member extending in the horizontal direction of the interconnect board, and the rigidity of the board can be increased. Particularly, in the case of a coreless board, there is a risk of a decrease in board rigidity, and therefore, such a structure is preferable.

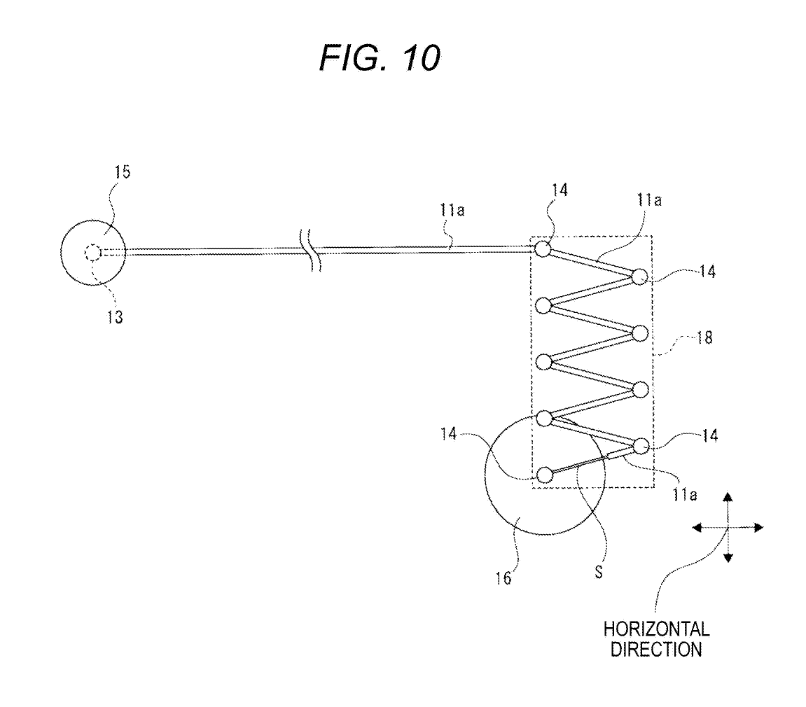

As shown in FIG. 10, so as to reduce impedance mismatching, the extended portion (denoted by “S” in the drawing) of the interconnect 11a from a back-surface-side electrode pad 16 may be made thinner to increase parasitic inductance.

With this arrangement, the amount of inductance can be further increased. Accordingly, the number of loops in the conductor loop 18 can be reduced, and the conductor loop 18 can be made even smaller in size.

Also, in the above description, the structure for reducing impedance mismatching in accordance with the present technique is provided on the side of the back-surface-side electrode pads 16 serving as the portions for connecting to the motherboard 100. However, in a case where there is a problem of impedance mismatching at the portions for connecting to the semiconductor electronic component 2, the structure for reducing impedance mismatching in accordance with the present technique can be provided on the side of the front-surface-side electrode pads 15.

In this case, one end of a conductor loop 18 is located on a front-surface-side electrode pad 15, to further enhance the effect to reduce impedance mismatching. Also, the insertion member 19 can be placed inside a conductor loop 18 as in the second embodiment.

In the above description, the present technique is applied to interconnect boards that are coreless boards. However, the present technique can also be suitably applied to interconnect boards each including a core layer.

The effects disclosed in this specification are merely examples and do not limit the present technique, and other effects may also be achieved.

It should be understood by those skilled in the art that various modifications, combinations, sub-combinations and alterations may occur depending on design requirements and other factors insofar as they are within the scope of the appended claims or the equivalents thereof.

### 4. Present Technique

The present technique can be embodied in the structures described below.

(1)

An interconnect board including:

interconnect layers and insulating layers that are alternately stacked;

vias that electrically connect the interconnect layers;

front-surface-side electrode pads formed on the front-surface side; back-surface-side electrode pads that are formed on the back-surface side and are arranged in an array; and

a conductor loop that is formed in a conductor path connecting one of the front-surface-side electrode pads and one of the back-surface-side electrode pads, the conductor loop being formed with interconnects in the interconnect layers and the vias, the conductor loop extending in a direction perpendicular to the thickness direction of the interconnect board.

(2)

The interconnect board of (1), wherein one end of the conductor loop is located on the one of the back-surface-side electrode pads.

(3)

The interconnect board of (1) or (2), wherein an insertion member made of a different material from the material of the insulating layers is placed inside the conductor loop.

(4)

The interconnect board of (3), wherein a magnetic material is placed inside the conductor loop.

(5)

The interconnect board of any one of (1) through (4), which is a coreless board.

(6)

The interconnect board of any one of (1) through (5), wherein the conductor loop is formed for each conductor path in a pair of conductor paths for transmitting signals by a differential method, and

the conductor loops formed in the pair of the conductor paths have the opposite loop directions from each other between the front-surface-side electrode pads and the back-surface-side electrode pads.

### REFERENCE SIGNS LIST

1,1A Interconnect board

2 Semiconductor electronic component

3 Semiconductor device

11 Interconnect layer

11a Interconnect

12 Insulating layer

13 Via

14 Stacked via

15 Front-surface-side electrode pad

16 Back-surface-side electrode pad

18 Conductor loop

19 Insertion member

1. An interconnect board comprising:
a plurality of interconnect layers and a plurality of insulating layers alternately stacked;
a plurality of vias electrically connecting the interconnect layers; a plurality of front-surface-side electrode pads formed on a front-surface side;
a plurality of back-surface-side electrode pads formed on a back-surface side and arranged in an array; and
a conductor loop formed in a conductor path connecting one of the front-surface-side electrode pads and one of the back-surface-side electrode pads, the conductor loop being formed with interconnects in the interconnect layers and the vias, the conductor loop extending in a direction perpendicular to a thickness direction of the interconnect board.

2. The interconnect board according to claim 1, wherein one end of the conductor loop is located on the one of the back-surface-side electrode pads.

3. The interconnect board according to claim 1, wherein an insertion member made of a different material from the material of the insulating layers is placed inside the conductor loop.

4. The interconnect board according to claim 3, wherein a magnetic material is placed inside the conductor loop.

5. The interconnect board according to claim 1, which is a coreless board.

6. The interconnect board according to claim 1, wherein
the conductor loop is formed for each conductor path in a pair of conductor paths for transmitting signals by a differential method, and
the conductor loops formed in the pair of the conductor paths have the opposite loop directions from each other between the front-surface-side electrode pads and the back-surface-side electrode pads.

7. A semiconductor device comprising:
an interconnect board including:
a plurality of interconnect layers and a plurality of insulating layers alternately stacked;
a plurality of vias electrically connecting the interconnect layers;
a plurality of front-surface-side electrode pads formed on a front-surface side;
a plurality of back-surface-side electrode pads formed on a back-surface side and arranged in an array; and
a conductor loop formed in a conductor path connecting one of the front-surface-side electrode pads and one of the back-surface-side electrode pads, the conductor loop being formed with interconnects in the interconnect layers and the vias, the conductor loop extending in a direction perpendicular to a thickness direction of the interconnect board; and
a semiconductor electronic component electrically connected to the interconnect board via the front-surface-side electrode pads.
